(19) United States
(12) Patent Application Publication
(10) Pub. No.: US 2008/0317185 A1
(43) Pub. Date: Dec. 25, 2008

(54) DUAL PHASE LOCKED LOOP (PLL) ARCHITECTURE FOR MULTI-MODE OPERATION IN COMMUNICATION SYSTEMS

(75) Inventors: Stephen A. Mueller, Foothill Ranch, CA (US); Jeffrey Putnam, Irvine, CA (US); Xuguang (Gary) Zhang, Aliso Viejo, CA (US)

Correspondence Address: FIALA & WEAVER, P.L.L.C.;C/O INTELLEVATE, P.O. BOX 52050, MINNEAPOLLS, MN, 55402, US

(73) Assignee: BROADCOM CORPORATION, Irvine, CA (US)

(21) Appl. No.: 11/874,748

(22) Filed: Oct. 18, 2007

Related U.S. Application Data
(60) Provisional application No. 60/946,070, filed on Jun. 25, 2007.

(51) Int. Cl. H03D 3/24

(52) U.S. Cl. 375/376

(57) ABSTRACT

The clock generating portion of a communication system includes a low-power, high-jitter phase locked loop (PLL) and a high-power, low-jitter PLL. Control logic within the chip allows for selective switching between the low-power and high-power PLL for receiving the broadcast signals, such as mobile TV signals. The switching may occur in a manner that is dependent on the conditions of the wireless channel and/or the complexity of the modulation scheme being used. The switching may be used to provide an oscillating signal from one or both of the PLLs to a receiver to be used to receive communication signals. The control logic may power off one of the PLLs to save power when not in use.

### BACKGROUND OF THE INVENTION

1. Field of the Invention

The present invention relates to communication systems, and in particular, to the handling of clock jitter in communication circuits.

2. Background Art

Mobile devices are relatively small sized portable computing devices that can perform a variety of functions. Mobile devices include laptop computers, handheld devices such as mobile phones (e.g., cell phones), handheld computers (e.g., personal digital assistants (PDAs), Palm Pilots™, etc.), handheld music players, and further types of mobile devices. Such mobile devices may be sized to rest on a user's lap, fit in the user's hand or pocket, or have other similarly small size. Mobile devices frequently have a small visual display screen for viewing output text and/or images, and a miniature keyboard, touch screen, click wheel, and/or other interface device for user input.

Many mobile devices include wireless communications capabilities. For instance, many mobile devices include circuits that enable the mobile devices to receive digital television signals, to receive digital radio signals, and/or to receive other types of signals and/or to communicate with networks. The communication circuits used in mobile devices must be designed to be small in size to conform to the small form factor of mobile devices.

Jitter is an unwanted variation of one or more signal characteristics in electronics and telecommunications. For example, jitter may be experienced in electronic characteristics such as pulse interval, or the amplitude, frequency, or phase of successive cycles. Jitter is a significant factor in the design of many communications links. Clock signals used in communication circuits may suffer from some degree of unwanted jitter. The increasingly denser and faster circuitry needed for mobile devices is becoming increasingly more susceptible to problems caused by clock signal jitter. Such jitter can adversely impact signal reception quality and the ability to receive signals by communication circuits, such as in digital audio, video, cellular, and other applications.

Thus, what is desired are ways of reducing the adverse effects of jitter in communication circuit clock signals.

### BRIEF SUMMARY OF THE INVENTION

Methods, systems, and apparatuses are provided for reducing the adverse effects of clock jitter in communication systems. In an example aspect, multiple oscillating signals are generated. For example, “N” oscillating signals may be generated, where N is any integer greater than or equal to 2. Each generated oscillating signal may be used as a clock signal by a receiver. Each oscillating signal has a corresponding amount of jitter. One of the oscillating signals may be enabled to be provided to a receiver circuit, depending on a tolerance for jitter by the receiver circuit. For example, a first phase locked loop (PLL) may generate a first oscillating signal having a first level of jitter. A second PLL may generate a second oscillating signal having a second level of jitter that is less than the first level of jitter. One of the first and second oscillating signals may be enabled to be provided to a particular receiver circuit according to the tolerance for jitter of the receiver circuit.

In a further aspect, an amount of power required for the first PLL may be less than an amount of power required for the second PLL. The first PLL may be used to clock circuits in a lower power, lower accuracy mode, while the second PLL may be used to clock circuits in a higher power, higher accuracy mode. Thus, the first PLL may be used when lower clock accuracy can be tolerated, while the second PLL may be used when higher accuracy is needed. When using the oscillating signal from the first PLL, the second PLL may be unpowered. In this manner, the benefit of having available an oscillating signal with a low level of jitter is attained, without having to consume the power necessary to generate the low jitter level oscillating signal in all situations.

The presence of both of the first and second PLLs enables the clocking of circuits, such as communication circuits, at a selected level of clock signal jitter, depending on the particular situation and the tolerance of the circuit for jitter. In further aspects, additional PLLs and/or other oscillating signal generators, such as a crystal oscillator, may be present to provide oscillating signals having further levels of jitter that may be provided to a receiver circuit. For example, “N” oscillating signal generators may be present. The additional PLLs and/or other oscillating signal generators may consume alternative levels of power, and may be powered if being used or unpowered when not being used, to provide further benefits with regard to consumption of power.

These and other objects, advantages and features will become readily apparent in view of the following detailed description of the invention. Note that the Summary and Abstract sections may set forth one or more, but not all exemplary embodiments of the present invention as contemplated by the inventor(s).

### BRIEF DESCRIPTION OF THE DRAWINGS/FIGURES

The accompanying drawings, which are incorporated herein and form a part of the specification, illustrate the present invention and, together with the description, further serve to explain the principles of the invention and to enable a person skilled in the pertinent art to make and use the invention.

FIG. 1 shows a block diagram of a mobile device, according to an embodiment of the present invention.

FIG. 2 shows a clock generating system, according to an example embodiment of the present invention.

FIG. 3 shows a clock generating system, according to another example embodiment of the present invention.

FIG. 4 shows a block diagram of a communication module, according to an example embodiment of the present invention.

FIG. 5 shows a communication module, according to another embodiment of the present invention.

FIG. 6 shows a flowchart providing example steps for providing clock signals to a receiver, according to an embodiment of the present invention.

FIG. 7 shows a flowchart providing example steps for determining a performance mode for a receiver, according to an embodiment of the present invention.

FIG. 8 shows a flowchart providing example steps for initializing a receiver mode, according to an embodiment of the present invention

FIG. 9 shows a clock generating system, according to an embodiment of the present invention.

The present invention will now be described with reference to the accompanying drawings. In the drawings, like reference numbers indicate identical or functionally similar elements. Additionally, the left-most digit(s) of a reference number identifies the drawing in which the reference number first appears.

### DETAILED DESCRIPTION OF THE INVENTION

### Introduction

The present specification discloses one or more embodiments that incorporate the features of the invention. The disclosed embodiment(s) merely exemplify the invention. The scope of the invention is not limited to the disclosed embodiment(s). The invention is defined by the claims appended hereto.

References in the specification to “one embodiment,” “an embodiment,” “an example embodiment,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to effect such feature, structure, or characteristic in connection with other embodiments whether or not explicitly described.

Furthermore, it should be understood that spatial descriptions (e.g., “above,” “below,” “up,” “left,” “right,” “down,” “top,” “bottom,” “vertical,” “horizontal,” etc.) used herein are for purposes of illustration only, and that practical implementations of the structures described herein can be spatially arranged in any orientation or manner.

### Example Communication Systems

Embodiments of the present invention can be incorporated into communication systems, such as cellular networks, wireless local area networks (WLANs), wirelessly broadcast digital television systems, wirelessly broadcast digital radio systems, and other types of communication systems. For example, mobile television (TV) communication systems provide TV services to mobile devices, such as cell phones, handheld mobile computers (e.g., personal digital assistants (PDAs), BLACKBERRY devices, PALM devices, etc.), music players (e.g., MP3 players, IPOD devices, etc.), laptop computers, etc., over mobile telecommunications networks. Mobile TV enables users to access TV related content on their mobile devices. Video, audio, and interactive content may be provided by mobile TV broadcasts. Many broadcasters already provide mobile TV broadcasts, and the numbers of such broadcasts in the marketplace are steadily increasing.

Mobile TV signals from broadcasters are being broadcast according to numerous mobile TV standards. Example mobile TV standards include digital video broadcasting-handheld (DVB-H), digital multimedia broadcasting (DMB), TDtv, Iseg, DAB, and MediaFLO.

Integrating communications systems into mobile devices, such as mobile TV communications systems, provides design challenges due to their small size. Avoiding problems due to jitter provides circuit design difficulties. Jitter is an unwanted variation of one or more signal characteristics in electronics and telecommunications. Jitter may be experienced in electronic characteristics such as pulse interval, and/or the amplitude, frequency, or phase of successive cycles. Clock signals used in the communication circuits may suffer from unwanted jitter. The increasingly denser and faster circuitry needed for mobile devices is becoming increasingly more susceptible to problems caused by clock signal jitter. Such jitter can adversely impact signal reception quality and the ability to receive signals by communication circuits, such as digital audio, video, cellular and other communication signals.

Embodiments of the present invention overcome problems with clock signal jitter in communication systems such as mobile TV communications circuits. Example embodiments of the present invention are described in detail in the following section.

### EXAMPLE EMBODIMENTS

The example embodiments described herein are provided for illustrative purposes, and are not limiting. The examples described herein may be adapted to various types of mobile communications systems, including cellular networks, wireless local area network(s), digital radio systems, etc. Furthermore, additional structural and operational embodiments, including modifications/alterations, will become apparent to persons skilled in the relevant art(s) from the teachings herein.

In embodiments, multiple clocking signals may be generated having various amounts of jitter. For example, a first phase locked loop (PLL) may generate a first oscillating signal and a first level of jitter. A second PLL may generate a second oscillating signal having a second level of jitter that is less than the first level of jitter. The frequency of the first and second oscillating signals may be the same. An amount of power required for the first PLL may be less than an amount of power required for the second PLL. The first PLL may be used to clock circuits in a lower power, lower accuracy mode, while the second PLL may be used to clock circuits in a higher power, higher accuracy mode. Thus, the first PLL may be used when lower accuracy can be tolerated, while the second PLL may be used when higher accuracy is needed. Furthermore, the PLL that is not being used during any particular time period may be unpowered to save power.

The presence of both of the first and second PLLs provides for clocking of circuits, such as communication circuits, at one or more levels of clock signal jitter, depending on the particular situation and the tolerance of the circuit for jitter. A higher accuracy PLL may be used to generate a clock signal with less jitter when higher accuracy is desired. Furthermore, power may be conserved by using a lower power PLL to generate a clock signal when higher clock signal jitter may be tolerated. Further PLLs and/or other types of clock signal generating elements may be present to provide clock signals with additional levels of jitter at other levels of power consumption, to handle an even further variety of situations.

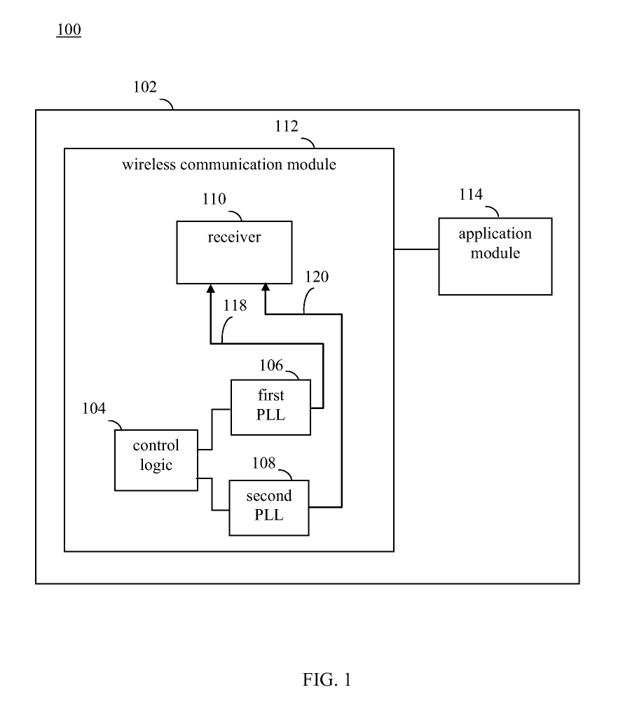

For example, FIG. 1 shows a block diagram of a mobile device 102, according to an embodiment of the present invention. Mobile device 102 may be any type of mobile device, including a cell phone, a handheld mobile computer (e.g., a personal digital assistant (PDA), a BLACKBERRY device, a PALM device, etc.), a music player (e.g., a MP3 player, an IPOD device, etc.), a laptop computer, or other type of mobile device. As shown in FIG. 1, mobile device 102 includes a wireless communication module 112 and an application module 114. Mobile device 102 may include functionality further than shown in FIG. 1, as would be known to persons skilled in relevant art(s). However, such additional functionality is not shown in FIG. 1 for purposes of brevity.

Application module 114 includes functionality for enabling one or more applications in mobile device 102, such as digital radio and/or music player capability, functionality for engaging in a telephone call, functionality for viewing video images such as mobile television images, a user interface, etc. For example, with regard to mobile television, application module 114 may include a CODEC (coder-decoder) for decoding a particular type of video data received by wireless communications module 112, a keypad, a knob, or other interface for selecting a channel, a display showing a tuned channel and/or other information, and/or further components enabling mobile TV.

Wireless communication module 112 includes functionality to enable mobile device 102 to perform wireless communications with remote entities. For example, wireless communications module 112 may enable communications by mobile device 102 according to one or more standards, including the mobile TV digital video broadcasting-terrestrial (DVB-T) standard, the digital video broadcasting-handheld (DVB-H) standard, or other mobile television communication standard(s). For further description of DVH-B, refer to “Digital Video Broadcasting (DVB); Transmission System for Handheld Terminals (DVB-H),” ETSI EN 302 304 V11.1 (2004-11), European Broadcasting Union, European Telecommunications Standards Institute, Copyright 2004, which is incorporated herein by reference in its entirety. Wireless communication module 112 may be implemented in hardware, software, firmware, or any combination thereof.

In the embodiment of FIG. 1, wireless communication module 112 includes a receiver 110. Receiver 110 may be configured in any manner to receive radio frequency signals for mobile device 102. For example, receiver 110 may include one or more mixers and/or other circuit elements for down-converting radio frequency signals.

As shown in FIG. 1, wireless communication module 112 further includes a control logic 104, a first phase locked loop (PLL) 106, and a second phase locked loop 108. Control logic 104 is configured to enable one of first PLL 106 and second PLL 108 according to a determined mode for receiver 110. When first PLL 106 is enabled, first PLL 106 generates a first oscillating signal 118 having an oscillating frequency and a first jitter level. When second PLL 108 is enabled, second PLL 108 generates a first oscillating signal 118 having the oscillating frequency and a second jitter level. Receiver 110 may use one or both of first and second oscillating signals 118 and 120 to perform functions, including clocking various circuits of receiver 110. The first jitter level of first oscillating signal 118 is higher than the second jitter level of second oscillating signal 120. Thus, second PLL 106 can be enabled to provide second oscillating signal 120 to receiver 110 when receiver 110 performs functions requiring less jitter/higher clock accuracy. First PLL 106 can be enabled to provide first oscillating signal 118 to receiver 110 when receiver 110 performs functions that can tolerate higher jitter/less clock accuracy.

First and second PLLs 106 and 108 may be any type(s) of phase locked loop(s), including analog or digital. PLLs typically generate oscillating signals having a fixed relation to the phase of a reference signal. The reference signal may be any oscillating signal, such as an output of a crystal oscillator or other oscillator type. First and second PLLs 106 and 108 include circuits that respond to both the frequency and the phase of the reference signal, raising or lowering the frequency of an oscillating signal generated by a controlled oscillator, until it matches the reference signal in both frequency and phase. In an embodiment, first and second PLLs 106 and 108 may each include a phase detector, a variable oscillator (e.g., a voltage controlled oscillator (VCO)), and a feedback path. A frequency divider may be present in the feedback path to make the PLL output frequency a multiple of the reference frequency. The phase detector compares a phase between the reference signal and an output of the variable oscillator, and varies a control signal to the variable oscillator according to the phase difference to increase or decrease a frequency of the variable oscillator. A low-pass filter may be present to smooth out abrupt changes in the control voltage. The output of a PLL is typically the output signal of the variable oscillator, but in some cases may be the control signal provided to the variable oscillator.

As described above, second oscillating signal 120 generated by first PLL 108 contains less jitter than an amount of jitter on first oscillating signal 118 generated by first PLL 106. Second PLL 108 may include circuit components having higher accuracy, tighter fabrication tolerances, lower noise issues, and/or other performance advantages over components of first PLL 106 to create less output jitter. For example, second PLL 108 may include a phase detector, variable oscillator, frequency divider, low-pass filter, and/or other circuit component that are higher quality when compared with similar components of first PLL 106. Furthermore, second PLL 108 may have a more complex PLL configuration than first PLL 106 (e.g., more components, a more advanced design and layout, etc.), and/or other differences from first PLL 106, to enable less output jitter. Due to the increased performance of second PLL 108 as compared to first PLL 106, however, second PLL 108 may consume more power than first PLL 106.

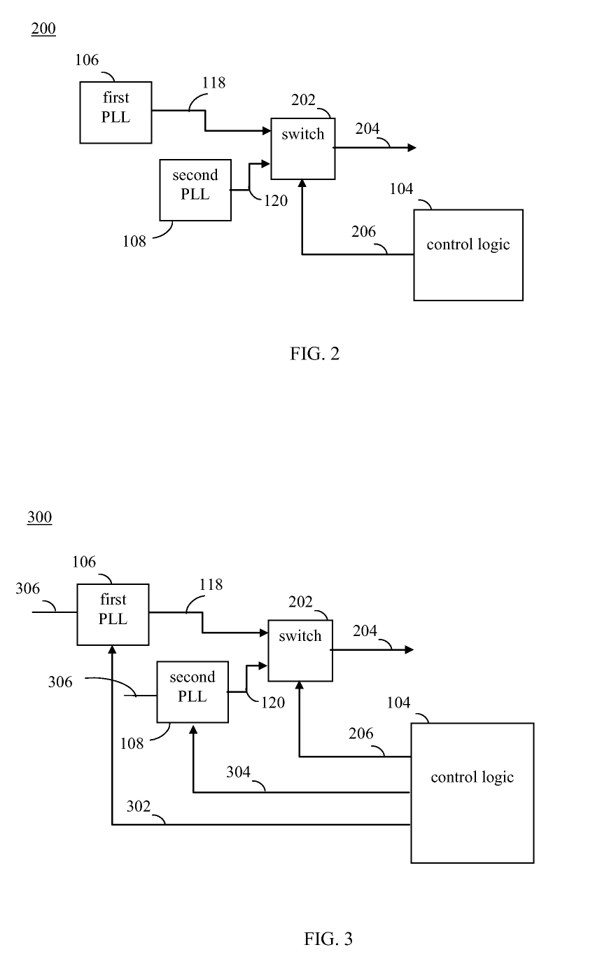

Control logic 104, first PLL 106, and second PLL 108 may be coupled together in any manner to enable oscillating signal 118 or oscillating signal 120 to be provided to receiver 110. For example, FIG. 2 shows a clock generating system 200, according to an example embodiment of the present invention. As shown in FIG. 2, system 200 includes first PLL 106, second PLL 108, control logic 104, and a switch 202. Switch 202 has a first input that receives first oscillating signal 118 and a second input that receives second oscillating signal 120. Control logic 104 generates a control signal 206. Switch 202 has a control input that receives control signal 206 from control logic 104. Switch 202 has an output that provides a selected oscillating signal 204, which is first oscillating signal 118 or second oscillating signal 120, as selected according to control signal 206.

Note that switch 202 may be any type of switch, as would be known to persons skilled in the relevant art(s). For example switch 202 may include one or more logic gates in hardware, software, firmware, or any combination thereof, one or more transistors, such as MOSFETs (metal-oxide-semiconductor field effect transistors) or other transistor type, and/or other element configured to perform switching.

FIG. 3 shows a clock generating system 300, according to another example embodiment of the present invention. Clock generating system 300 is generally similar to system 200 shown in FIG. 2, with the addition of power control functionality. The embodiment of FIG. 3 enables one of first and second PLLs 106 and 108 that is not providing an oscillating signal to receiver 110 to be unpowered, to save overall power consumption. As shown in FIG. 3, control logic 104 generates a first power enable signal 302 and a second power enable signal 304. First power enable signal 302 is received by first PLL 106, and second power enable signal 304 is received by second PLL 108. First and second power enable signals 302 and 304 respectively enable or disable power to first and second PLLs 106 and 108.

For example, as shown in FIG. 3, first and second PLLs 106 and 108 each receive a power signal 306, which may include one or more supply voltages used to power circuitry of first and second PLLs 106 and 108. When first oscillating signal 118 of first PLL 106 is selected to be provided to receiver 110, control logic 104 generates first power enable signal 302 to enable PLL 106 to receive power signal 306, and generates second power enable signal 304 to disable power signal 306 from powering second PLL circuit 108. When second oscillating signal 120 of second PLL 108 is selected to be provided to receiver 110, control logic 104 generates first power enable signal 302 to disable power signal 306 from powering PLL 106, and generates second power enable signal 304 to enable second PLL circuit 108 to receive power signal 306.

For example, first and second PLLs 106 and 108 may each include one or more switching elements, such as transistors or logic gates, to gate power signal 306 to respective PLL circuitry based on first and second power enable signals 302 and 304, respectively. In an alternative embodiment, a single power enable signal may generated by control logic 104 to be received by both of first and second PLLs 106 and 108 (instead of generating two signals 302 and 304) to enable or disable power signal 306 at first and second PLLs 106 and 108. For example, a high value on the power enable signal may enable power signal 306 to power first PLL 106 while disabling power signal 306 at second PLL 108. A low value on the power enable signal may disable power signal 306 at first PLL 106 while enabling power signal 306 to power second PLL 108. In an embodiment, the single power enable signal may be control signal 206, or may be a signal separate from control signal 206.

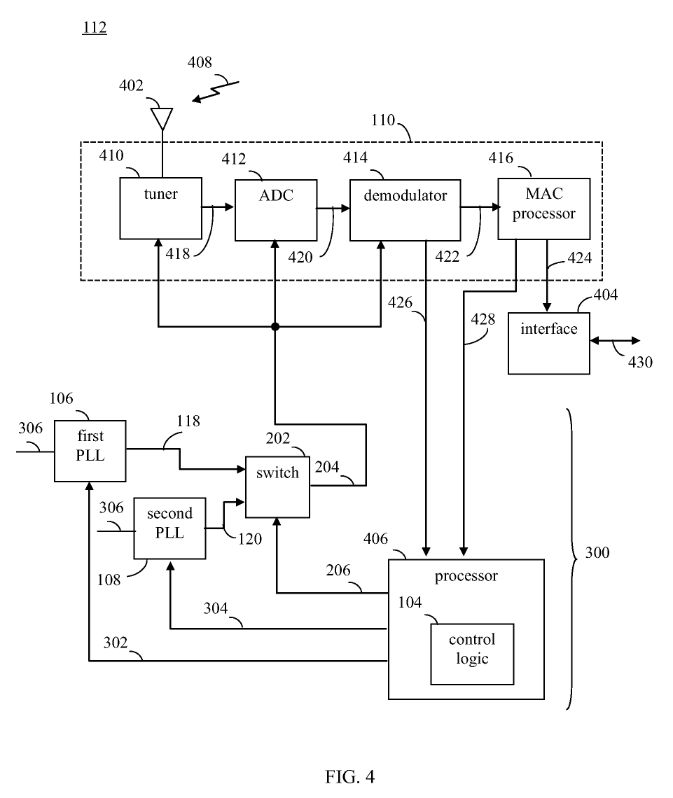

Receiver 110 of communication module 112 shown in FIG. 1 may be configured in any manner for receiving modulated radio frequency signals, as would be known to persons skilled in the relevant art(s). Receiver 110 may be an analog receiver, a digital receiver, or may be a mixture of analog and digital. FIG. 4 shows a block diagram of communication module 112, according to an example embodiment of the present invention. As shown in FIG. 4, communication module 112 includes receiver 110, an antenna 402, an interface 404, a processor 406, and clock generating system 300. In the embodiment of FIG. 4, receiver 110 includes a tuner 410, an analog-to-digital converter (ADC) 412, a demodulator 414, and a media access controller (MAC) processor 416. Processor 406 includes control logic 300.

Antenna 402 is configured to receive a modulated radio frequency (RF) signal 408. For example, in a video application, modulated RF signal 408 may include video (e.g., television) data modulated on a radio frequency carrier according any video communication standard. For instance, in a mobile TV embodiment, modulated RF signal 408 may be one of a digital video broadcasting-terrestrial (DVB-T), digital video broadcasting-handheld (DVB-H—which is a superset of DVB-T) signal, a DVB-SH (satellite services to handheld devices) signal, a digital multimedia broadcasting (DMB) signal (e.g., T-DMB or S-DMB), a TDtv signal, a 1seg signal, a DAB signal, a MediaFLO signal, or other type of mobile TV signal. Antenna 402 may be any type of antenna suitable for receiving RF signals in a mobile device.

Tuner 410 is coupled to antenna 402, and receives modulated RF signal 408 from antenna 402. Tuner 410 is configured to down-convert modulated RF signal 408 to a down-converted modulated signal 418 that includes modulated data, such as modulated video data. Tuner 410 may include one or more mixers, switches, and/or other circuit elements configured to perform frequency down-conversion. In one embodiment, tuner 410 contains an oscillating signal generator. In another embodiment, tuner 410 receives selected oscillating signal 204 generated by clock generating system 300, as shown in FIG. 4.

ADC 412 receives down-converted modulated signal 418, and converts down-converted modulated signal 418 from an analog signal to a digital signal. ADC 412 generates a digital modulated signal 420. ADC 412 may include any type of analog-to-digital converter, as would be known to persons skilled in the relevant art(s). In an embodiment, as shown in FIG. 4, ADC 412 converts down-converted modulated signal 418 to digital modulated signal 420 according to selected oscillating signal 204 received from switch 202.

Demodulator 414 receives digital modulated signal 420. Digital modulated signal 420 may include data modulated according to any modulation scheme, such as frequency modulation (FM), phase modulation (PM), amplitude modulation (AM), a quadrature modulation scheme, such as quadrature amplitude modulation (QAM) of any M-ary (e.g., 4-QAM, 16-QAM, 64-QAM, 256-QAM, etc.) or quadrature phase shift keying (QPSK), or other modulation type. For example, when modulated RF signal 408 is a DVB-H standard signal, digital modulated signal 420 may include data modulated according to QAM or QPSK. In FIG. 4, demodulator 414 demodulates digital modulated signal 420 according to selected oscillating signal 204 to generate a data signal 422. Data signal 422 may include video data, such as television data formatted according to a mobile TV standard mentioned above or otherwise known. Embodiments for demodulator 414 for demodulating various modulation schemes are well known to persons skilled in the relevant art(s).

MAC processor 416 receives data signal 422, and performs media access control processing, as would be known to persons skilled in the relevant art(s). MAC processor 416 generates output signal 424, which may include data of data signal 422 formatted into IP (internet protocol) packets or other form. Interface 404 receives output signal 424. Interface 404 provides an interface for communication module 112 with application module 114 shown in FIG. 1. Interface 404 may be any type of interface, proprietary or conventional, such as a USB (universal standard bus) interface, an Ethernet interface, or other interface type. Interface 404 transmits data from communication module 112 over a communication link 430. Interface 404 may also receive commands and/or other information transmitted to communication module 112 over communication link 430. For example, in an embodiment, interface 404 may transmit television data over communication link 430 to application module 114, which may include a display for displaying the television data.

Processor 406 may be optionally present in communication module 112 to perform control functions with regard to receiver 110, interface 404, and clock generating system 300. For example, as shown in FIG. 4, when processor 406 is present, control logic 104 may be implemented in processor 406. Processor 406 may be any type of processor, including a microprocessor, a microcontroller, a block of processor logic (hardware, software, and/or firmware), or other form of processor, as would be known to persons skilled in the relevant art(s).

In embodiments, any one or more of tuner 410, ADC 412, demodulator 414, and/or further circuits of receiver 110 may receive selected oscillating signal 204. In the embodiment of FIG. 4, each of tuner 410, ADC 412, and demodulator 414 receive selected oscillating signal 204, and thus receive the selected one of first and second oscillating signals 118 and 120. In other embodiments, tuner 410, ADC 412, and demodulator 414 (and/or further circuits of receiver 110) may receive any combination of first and second oscillating signals 118 and 120.

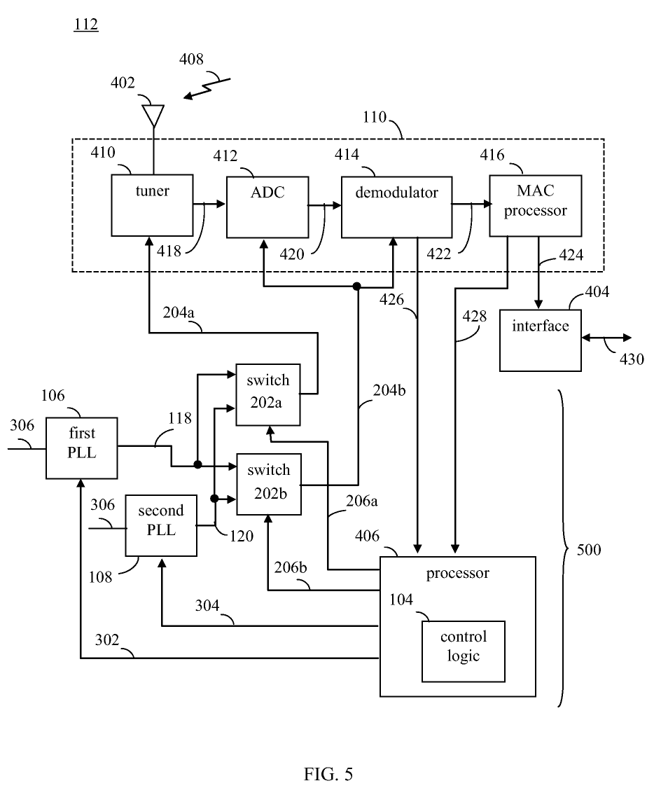

For example, FIG. 5 shows a block diagram of communication module 112, according to another embodiment of the present invention. As shown in FIG. 5, communication module 112 includes a clock generating system 500, similar to clock generating system 300 shown in FIGS. 3 and 4, with differences described as follows. In the embodiment of FIG. 5, a first switch 202a and a second switch 202b are present. Both of first and second switches 202a and 202b receive first and second oscillating signals 118 and 120 at respective inputs. First switch 202a receives a first control signal 206a from control logic 104 in processor 406, and second switch 202b receives a second control signal 206a from control logic 104 in processor 406. First switch 202a outputs a first selected oscillating signal 204a, which is received by tuner 410 of receiver 110. Second switch 202b outputs a second selected oscillating signal 204b, which is received by ADC 412 and demodulator 414 of receiver 110.

Control logic 104 generates first control signal 206a to enable first switch 202a to transmit a selected one of first and second oscillating signals 118 and 120 as first selected oscillating signal 204a, to be received and used by tuner 410. Control logic 104 generates second control signal 206b to enable second switch 202b to transmit a selected one of first and second oscillating signals 118 and 120 as second selected oscillating signal 204b, to be received and used by ADC 412 and demodulator 414. In further embodiments, any number of switches 202 controlled by control logic 104 may be present to provide any number of selected oscillating signals 204 to be received by tuner 410, ADC 412, demodulator 414, and/or further circuits of receiver 110, in any combination.

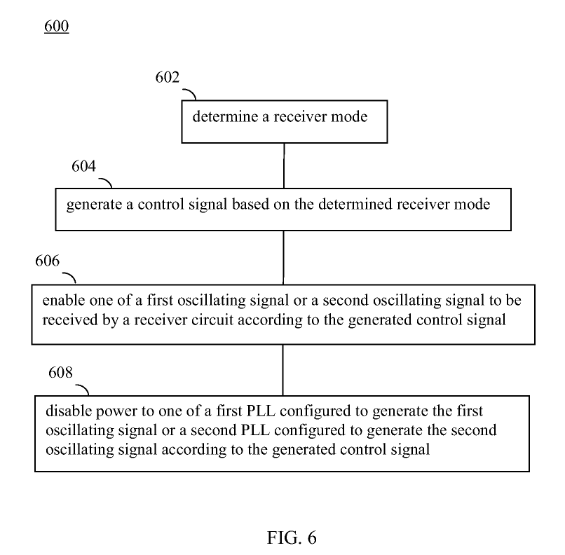

Control logic 104 may be configured in any manner to perform its functions. For example, FIG. 6 shows a flowchart 600 providing example steps for providing a clock signal to a receiver, according to an embodiment of the present invention. For instance, control logic 104 of FIG. 4 may operate according to flowchart 600, in an embodiment. Other structural and operational embodiments will be apparent to persons skilled in the relevant art(s) based on the discussion regarding flowchart 600. Flowchart 600 is described as follows.

Flowchart 600 begins with step 602. In step 602, a receiver mode is determined. The receiver mode that is determined in step 602 may be a performance mode for operation of receiver 110. Receiver 110 may be capable of operating at different levels of performance, such as a high performance mode, a medium performance mode, a low performance mode, etc. A high performance mode for receiver 110 may require a clock signal to have a low level of jitter so that clock signal accuracy is increased, while in a low performance mode, receiver 110 may tolerate the clock signal having a higher level of jitter. A performance mode of receiver 110 may be determined based on any number of factors, including an operational mode of receiver 110 (e.g., sleep mode, burst mode, etc.), a received signal quality level, a communication mode of receiver 110 (e.g., a particular modulation scheme of the received signal, etc.), and/or other factors. In an embodiment, such as shown in FIG. 5, different circuits of receiver 110 may have different determined performance modes, and thus may receive different oscillating signals.

In step 604, a control signal is generated based on the determined receiver mode. For example, as shown in FIG. 4, control logic 104 generates control signal 206. Control signal 206 may be an analog or digital signal. Control signal 206 is generated to indicate the receiver mode. For example, in a digital signal embodiment, a first digital value (e.g., a “0” bit value) may indicate a low performance mode, and a second digital value (e.g., a “1” bit value) may indicate a high performance mode. As shown in FIG. 5, in an embodiment, multiple control signals 206 (e.g., signals 206a and 206b) may be generated by control logic 104, corresponding to the performance modes of different circuits of receiver 110.

In step 606, one of a first oscillating signal or a second oscillating signal is enabled to be received by a receiver circuit according to the generated control signal. For example, as shown in FIG. 4, switch 202 transmits one of first and second oscillating signals 118 and 120 as selected oscillating signal 204 depending on the value of control signal 104. Selected oscillating signal 204 has the jitter level of the corresponding one of first and second oscillating signals 118 and 120 that was selected. Selected oscillating signal 204 is received by tuner 410, ADC 412, and demodulator 414. Tuner 410, ADC 412, and demodulator 414 perform their various functions (e.g., as described above) using selected oscillating signal 204. For example, tuner 410 receives a modulated radio frequency signal and down-converts the received signal according to selected oscillating signal 204. ADC 412 converts the down-converted modulated (i.e., analog) signal to a digital modulated signal according to selected oscillating signal 204. Demodulator 414 demodulates the digital modulated signal according to selected oscillating signal 204 to generate a data signal. In embodiments, first and second oscillating signals 118 and 120 may be provided to tuner 410, ADC 412, and demodulator 414 in any combination.

Step 608 is optional. In step 608, power to one of a first PLL configured to generate the first oscillating signal or a second PLL configured to generate the second oscillating signal is disabled according to the generated control signal. For example, as shown in FIG. 4, control logic 104 may disable power signal 306 to one of first PLL 106 and second PLL 108, when not in use. In the embodiment of FIG. 5, circuits of receiver 110 may potentially receive both of first and second oscillating signals 118 and 120. Thus, in some cases, neither one of first and second PLLs 106 and 108 may be powered down.

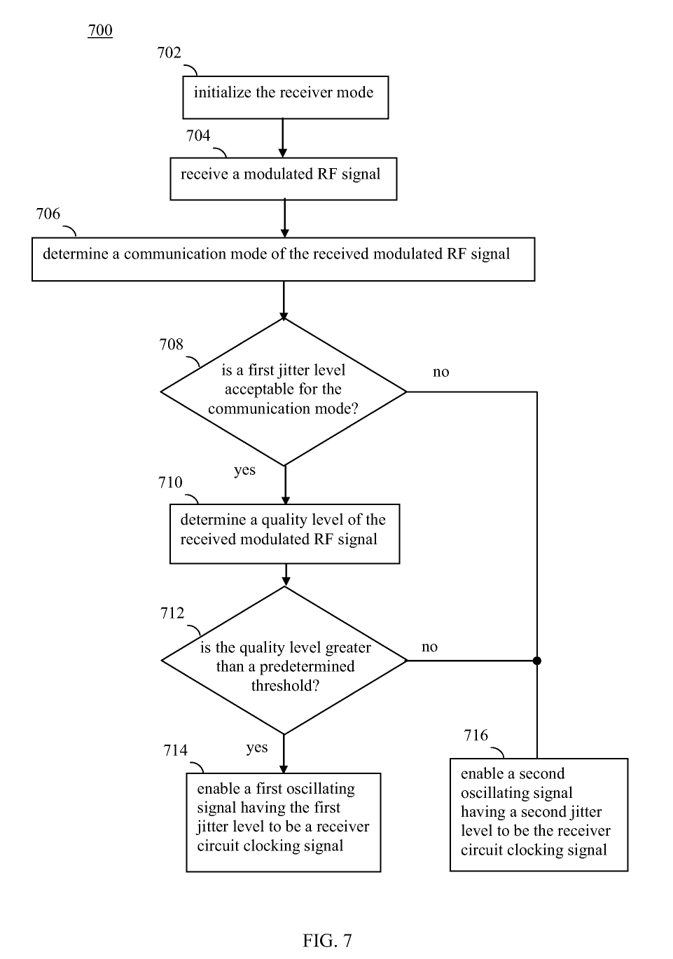

As described above, the performance mode of receiver 110 may be determined in step 602 in any manner. For example, FIG. 7 shows a flowchart 700 providing example steps for determining a performance mode for a receiver, according to an example embodiment of the present invention. Step 602 of flowchart 600 may be performed according to flowchart 700, in an embodiment. Other structural and operational embodiments will be apparent to persons skilled in the relevant art(s) based on the discussion regarding flowchart 700. Flowchart 700 is described as follows.

Flowchart 700 begins with step 702. Step 702 is optional. In step 702, the receiver mode is initialized. For instance, the performance mode of receiver 110 may be initially selected to be high performance or low performance, and the corresponding one of first and second oscillating signals 118 and 120 can be provided to receiver 110 as selected oscillating signal 204. The initial receiver mode can be selected in any manner. For instance, the initial performance mode can always be selected to be a same one of high performance or low performance. In one example, high performance may be selected as the initial performance mode so that signals may be more likely to be successfully received than in a low performance mode. In another example, low performance may be selected as the initial performance mode to save power (second PLL 108 may be unpowered). Alternatively, the initial receiver mode can be selected based on an operational mode of receiver 110 (e.g., sleep mode, burst mode, etc.), an expected received signal quality level, an expected communication mode of receiver 110, etc.

In step 704, a modulated RF signal is received. For example, as described above, RF modulated signal 408 may be received by receiver 110. Receiver 110 receives RF modulated signal 408 according to an initial setting of selected oscillating signal 204, which may be determined in step 702.

In step 706, a communication mode of the received modulated RF signal is determined. The communication mode of RF modulated signal 408 may be determined by demodulator 414, and transmitted to control logic 104 on a communication mode indication signal 426, as shown in FIGS. 4 and 5. For example, the communication mode may be a modulation scheme of RF modulated signal 408. Example modulation schemes include 4-QAM, 16-QAM, 64-QAM, QPSK, and/or any other modulation scheme suitable for RF modulated signal 408, which may be a mobile TV or other type signal.

In step 708, whether a first jitter level is acceptable for the communication mode is determined. For instance, some modulation schemes may be demodulated more accurately by a clock signal having lower jitter, while others may be demodulated acceptably with a higher jitter level clock signal. In one example, 4-QAM and 16-QAM may be demodulated using a higher jitter level clock signal, while 64-QAM is preferably demodulated using a lower jitter level clock signal. If the relatively higher first jitter level is acceptable for the determined communication mode, operation proceeds to step 710. If the relatively higher first jitter level is not acceptable, operation proceeds to step 716.

In step 710, a quality level of the received modulated RF signal is determined. In an embodiment, a quality level of RF modulated signal 408 may be determined by MAC processor 416, and transmitted to control logic 104 as a quality level indication signal 428, as shown in FIGS. 4 and 5. The quality level may be based on any sort of quality measure known to persons skilled in the relevant art(s), such as a signal-to-noise ratio (SNR), a bit error rate (BER), a frame error rate (FER), adjacent channel interference, co-channel interference, Doppler effect, a channel profile, etc.

In step 712, whether the quality level is greater than a predetermined threshold is determined. A predetermined threshold between high performance mode and low performance mode for any quality measure may be determined for a particular application, in a manner as would be apparent to persons skilled in the relevant art(s). The quality level determined for a particular quality measure, and received on quality level indication signal 428, may be compared by control logic 104 to the corresponding predetermined threshold. If the quality level is greater than the predetermined threshold, operation proceeds to step 714. If the quality level is not greater than the predetermined threshold, operation proceeds to step 716. Note that steps 710 and 712 may be repeated for any number of quality measures, as desired for a particular application.

In step 714, a first oscillating signal having the first jitter level is enabled to be a receiver circuit clocking signal. For example, step 714 may be performed during step 606 of flowchart 600 shown in FIG. 6.

In step 716, a second oscillating signal having a second jitter level is enabled to be the receiver circuit clocking signal. For example, step 716 may be performed during step 606 of flowchart 600 shown in FIG. 6.

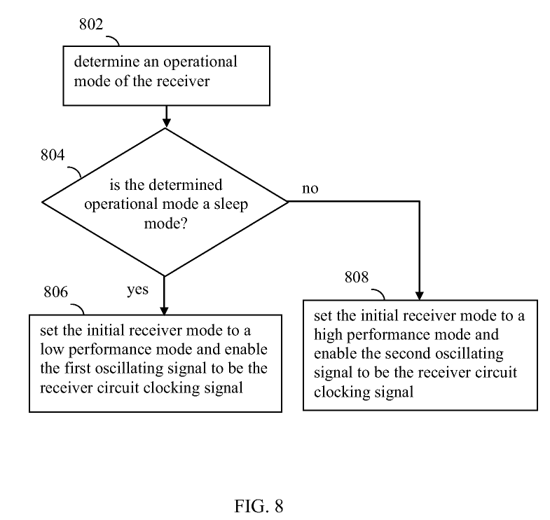

As described above, the receiver mode may be initialized in step 702 in any manner. For example, FIG. 8 shows a flowchart 800 providing example steps for initializing a receiver mode by determining an operational mode of the receiver, according to an example embodiment of the present invention. Flowchart 800 is described as follows.

In step 802, an operational mode of the receiver is determined. Depending on the particular type of receiver, receiver 110 may have multiple operational modes. For example, in some mobile TV applications, TV data is transmitted to receiver 110 on RF modulated signal 408 in relatively short bursts (a burst mode), where receiver 110 is active, followed by long periods of relative silence, where portions of receiver 110 (e.g., tuner 410, ADC 412) are largely inactive (e.g., a sleep mode). A ratio of the burst periods to the inactive periods may be 10% of the time versus 90% of the time. In an embodiment, the “burst mode” may be a period of time where high performance is desired, at least initially, for receiver 110, while the “sleep mode” may be a period of time where low performance is acceptable. Receiver 110 may have further or alternative operational modes, depending on the particular application.

In step 804, whether the determined operational mode is a sleep mode is determined. If the operational mode is determined to be a sleep mode, operation proceeds to step 806. If the operational mode is determined to not be a sleep mode, operation proceeds to step 808.

In step 806, the initial receiver mode is set to a low performance mode and the first oscillating signal is enabled to be the receiver circuit clocking signal. In step 806, because the operational mode is sleep mode, receiver 110 can be initialized to a low performance mode.

In step 808, the initial receiver mode is set to a high performance mode and the second oscillating signal is enabled to be the receiver circuit clocking signal. In step 808, because the operational mode is not sleep mode (e.g., may be burst mode), receiver 110 may be placed in a high performance mode.

In further embodiments, additional modes of operation of receiver 110 may be analyzed to determine an initial or subsequent performance mode for receiver 110.

### FURTHER EMBODIMENTS

Embodiments provide for selective switching between lower-power and higher-power PLLs for receiving signals, such as a DVB-H broadcast signal. The switching may occur in a manner that is dependent on the conditions of the wireless channel, the complexity of the modulation scheme being used, and/or based on other parameters/characteristics of the received signal, of the receiver, etc. Embodiments permit for intelligent and adaptive switching between a first mode of operation that conserves power and a second mode of operation that provides better performance. This is an advance over conventional systems that included only a single PLL tailored either for performance or for power.

Power management and conservation is a critical feature in the small form factor devices that implement mobile TV based on the DVB-H and other standards. By using a multi-PLL architecture, a chip can conserve power by using the low-power PLL when conditions are suitable to do so.

Although the embodiments are described above with respect to two PLLs, further PLLs and/or other clock generating mechanisms may be present to provide further grades of power consumption and signal jitter, as may be desirable in receiver implementations. For example, “N” oscillating signal generators may be present, where N is any integer greater than or equal to 2. The N oscillating signal generators generate N oscillating signals. Each oscillating signal contains a corresponding amount of signal jitter. An oscillating signal may be selected according to the current tolerance for jitter. The oscillating signal generator(s) other than a selected one may be powered down, to save power. For example, an oscillating signal/oscillating signal generator combination may be selected for a particular situation having a maximum tolerable jitter and minimum amount of power consumption.

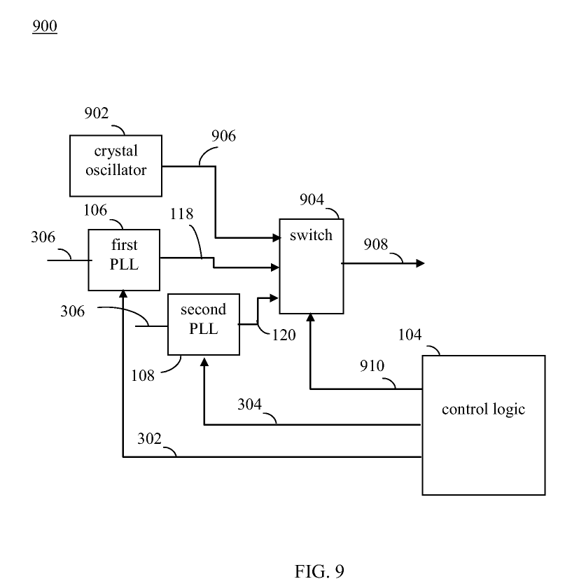

For example, FIG. 9 shows a clock generating system 900, according to an embodiment of the present invention. Clock generating system 900 is generally similar to clock generating system 300 in FIG. 3, with differences described as follows. As shown in FIG. 9, in addition to first and second PLLs 106 and 108, system 900 includes a crystal oscillator 902. Crystal oscillator 902 provides a third oscillating signal generation mechanism for system 900, having a particular level of jitter and power consumption.

As shown in FIG. 9, first PLL 106 generates first oscillating signal 118, second PLL 108 generates second oscillating signal 120, and crystal oscillator 902 generates a third oscillating signal 906. First, second, and third oscillating signals 118, 120, and 906 are received at respective inputs of a switch 904. Control logic 104 generates a control signal 910. Switch 904 has a control input that receives control signal 910 from control logic 104. Switch 904 has an output that provides a selected oscillating signal 908, which is first oscillating signal 118, second oscillating signal 120, or third oscillating signal 906 as selected by switch 904 according to control signal 910. Control logic 104 configures control signal 910 to enable switch 904 to transmit one of first, second, or third oscillating signals 118, 120, and 906 depending on a desired level of jitter and/or power consumption. Relative to first and second PLLs 106 and 108, crystal oscillator 902 consumes the lowest amount of power (approximately zero power), but suffers from the greatest amount of jitter. Thus, control logic 104 may select third oscillating signal 906 to be transmitted by switch 904 to a receiver in situations where a very high amount of jitter is acceptable, such as when receiver 110 is in a sleep mode. In such a situation, first and second PLLs 106 and 108 may be deprived of power, to place clock generating system 900 in a very low performance, very low power consumption mode. Control logic 104 may select first oscillating signal 118 to be transmitted by switch 904 in situations where an intermediate amount of jitter and an intermediate amount of power consumption is acceptable, and may select second oscillating signal 120 to be transmitted by switch 904 in situations where a low amount of jitter is desired and a relatively higher amount of power consumption is acceptable.

Furthermore, in system 900, multiple switches 904 may be present (in a similar fashion to the embodiment of FIG. 5), to enable different ones of first-third oscillating signals 118, 120, and 906 to be selected for different circuits of receiver 110.

### CONCLUSION

While various embodiments of the present invention have been described above, it should be understood that they have been presented by way of example only, and not limitation. It will be apparent to persons skilled in the relevant art that various changes in form and detail can be made therein without departing from the spirit and scope of the invention. Thus, the breadth and scope of the present invention should not be limited by any of the above-described exemplary embodiments, but should be defined only in accordance with the following claims and their equivalents.

What is claimed is:

1. An electrical circuit, comprising:
a first phase locked loop (PLL) circuit that generates a first oscillating signal having a first jitter level, the first PLL circuit consuming a first power during operation;
a second PLL circuit that generates a second oscillating signal having a second jitter level, the second PLL circuit consuming a second power during operation, wherein the first power is less than the second power, and the first jitter level is greater than the second jitter level; and
a control logic configured to enable the first oscillating signal to be received by a receiver circuit during a first receiver mode and to enable the second oscillating signal to be received by the receiver circuit during a second receiver mode.

2. The electrical circuit of claim 1, wherein the control logic is configured to enable a power signal to be applied to the first PLL circuit and to disable the power signal from being applied to the second PLL circuit during the first receiver mode; and
wherein the control logic is configured to enable the power signal to be applied to the second PLL circuit and to disable the power signal from being applied to the first PLL circuit during the second receiver mode.

3. The electrical circuit of claim 2, further comprising:
a switch that has a first input that receives the first oscillating signal and a second input that receives the second oscillating signal, wherein the switch has a control input that receives a control signal from the control logic, and wherein the switch has an output that provides the first oscillating signal or the second oscillating signal according to the received control signal;
wherein the receiver circuit is coupled to the switch output.

4. The electrical circuit of claim 3, further comprising:
a receiver that includes
a tuner that receives a modulated radio frequency signal and generates a down-converted modulated signal,
an analog-to-digital converter (ADC) that converts the down-converted modulated signal to a digital modulated signal, and
a demodulator that demodulates the digital modulated signal to generate a data signal.

5. The electrical circuit of claim 4, wherein at least one of the tuner, the ADC, and the demodulator has a clock input that is coupled to the switch output.

6. The electrical circuit of claim 4, wherein the modulated radio frequency signal is a radio frequency mobile television signal.

7. The electrical circuit of claim 3, further comprising at least one additional switch that has a first input that receives the first oscillating signal, a second input that receives the second oscillating signal, a control input that receives a corresponding control signal from the control logic, and an output that provides the first oscillating signal or the second oscillating signal according to the received control signal;
wherein the receiver circuit is coupled to the switch output of the at least one additional switch.

8. The electrical circuit of claim 3, wherein the switch has a third input that receives a crystal oscillator output oscillating signal, wherein the switch output provides the first oscillating signal, the second oscillating signal, or the crystal oscillator output oscillating signal according to the received control signal.

9. The electrical circuit of claim 1, wherein the first receiver mode is a low performance mode and the second receiver mode is a high performance mode.

10. A method for a communication system, comprising:
receiving a modulated radio frequency (RF) signal;
determining a communication mode of the received modulated RF signal;
enabling a second oscillating signal having a second jitter level to be a receiver circuit clocking signal if a first jitter level is not acceptable for the determined communication mode;
if the first jitter level is acceptable for the determined communication mode,
determining a quality level of the received modulated RF signal, and
enabling a first oscillating signal having the first jitter level to be the receiver circuit clocking signal if the determined quality level is greater than a predetermined threshold;
wherein the first jitter level is greater than the second jitter level.

11. The method of claim 10, further comprising:
determining an operational mode of a receiver;
enabling the first oscillating signal to be the receiver circuit clocking signal if the determined operational mode is a sleep mode; and
enabling the second oscillating signal to be the receiver circuit clocking signal if the determined operational mode is a burst mode.

12. The method of claim 10, wherein a first phase locked loop (PLL) circuit is configured to generate the first oscillating signal and a second PLL is configured to generate the second oscillating signal, the method further comprising:
removing a power signal from the second PLL circuit if the first oscillating signal is enabled to be the receiver circuit clocking signal; and
removing the power signal from the first PLL circuit if the second oscillating signal is enabled to be the receiver circuit clocking signal.

13. The method of claim 12, further comprising:
supplying a first amount of power to the first PLL circuit if the first oscillating signal is enabled to be the receiver circuit clocking signal; and
supplying a second amount of power to the second PLL circuit if the second oscillating signal is enabled to be the receiver circuit clocking signal;
wherein the first amount of power is less than the second amount of power.

14. The method of claim 10, further comprising performing at least one of:
down-converting a received modulated radio frequency signal to a down-converted modulated signal according to the one of the first oscillating signal and the second oscillating signal enabled to be the receiver circuit clocking signal;
converting the down-converted modulated signal to a digital modulated signal according to the one of the first oscillating signal and the second oscillating signal enabled to be the receiver circuit clocking signal; and
demodulating the digital modulated signal according to the one of the first oscillating signal and the second oscillating signal enabled to be the receiver circuit clocking signal.

15. A mobile device, comprising:
an integrated circuit chip that includes a first phase locked loop (PLL) circuit, a second PLL circuit, and a control logic;
wherein the first phase locked loop (PLL) circuit is configured to generate a first oscillating signal having a first jitter level, the first PLL circuit consuming a first power during operation;
wherein the second PLL circuit is configured to generate a second oscillating signal having a second jitter level, the second PLL circuit consuming a second power during operation, wherein the first power is less than the second power, and the first jitter level is greater than the second jitter level; and
wherein the control logic is configured to enable the first oscillating signal to be received by a receiver circuit during a first receiver mode and to enable the second oscillating signal to be received by the receiver circuit during a second receiver mode.

16. The mobile device of claim 15, wherein the control logic is configured to enable a power signal to be applied to the first PLL circuit and to disable the power signal from being applied to the second PLL circuit during the first receiver mode; and
wherein the control logic is configured to enable the power signal to be applied to the second PLL circuit and to disable the power signal from being applied to the first PLL circuit during the second receiver mode.

17. The mobile device of claim 16, wherein the integrated circuit chip further comprises:
at least one switch that has a first input that receives the first oscillating signal, a second input that receives the second oscillating signal, a control input that receives a control signal from the control logic, and an output that provides the first oscillating signal or the second oscillating signal according to the received control signal;
wherein the receiver circuit is coupled to the output of the at least one switch.

18. The mobile device of claim 17, wherein the integrated circuit chip further comprises:
a receiver that includes
a tuner that receives a modulated radio frequency signal and generates a down-converted modulated signal,
an analog-to-digital converter (ADC) that converts the down-converted modulated signal to a digital modulated signal, and
a demodulator that demodulates the digital modulated signal to generate a data signal.

19. The mobile device of claim 18, wherein at least one of the tuner, the ADC, and the demodulator has a clock input that is coupled to the output of the at least one switch.

20. The mobile device of claim 18, wherein the modulated radio frequency signal is a radio frequency mobile television signal.

21. The mobile device of claim 3, further comprising:
a crystal oscillator that generates an third oscillating signal, wherein the at least one switch has a third input that receives a crystal oscillator output oscillating signal, wherein the output of the at least one switch provides the first oscillating signal, the second oscillating signal, or the crystal oscillator output oscillating signal according to the received control signal.

22. The mobile device of claim 17, wherein the integrated circuit chip further includes a media access control (MAC) unit and a first interface;
wherein the mobile device further includes a host processor chip that includes a second interface that is communicatively coupled with the first interface.

23. The mobile device of claim 15, wherein the first receiver mode is a low performance mode and the second receiver mode is a high performance mode.

24. A mobile television (TV) integrated circuit chip, comprising:
a first phase locked loop (PLL) circuit, the first PLL consuming a first power during operation and having a first output jitter level during operation; and
a second PLL circuit, the second PLL consuming a second power during operation and having a second output jitter during operation; and
a control logic configured to selectively enable the first PLL and the second PLL;
wherein the first power is less than the second power, and the first jitter level is greater than the second jitter level;
wherein the control logic is configured to enable the first PLL during a low performance mode and to enable the second PLL during a high performance mode.

25. A method in a mobile television (TV) integrated circuit chip, comprising:
selectively enabling a first phase locked loop (PLL) during a low performance mode and a second PLL during a high performance mode.
